(19) United States
(12) Patent Application Publication
(10) Pub. No.: US 2006/0195744 A1
(43) Pub. Date: Aug. 31, 2006

(54) Method and apparatus to simulate automatic test equipment

(75) Inventor: Steven Petersen, Yorba Linda, CA (US)

Correspondence Address: STERNE, KESSLER, GOLDSTEIN & FOX PLLC, 1100 NEW YORK AVENUE, N.W., WASHINGTON, DC, 20005, US

(73) Assignee: Broadcom Corporation, Irvine, CA (US)

(21) Appl. No.: 11/125,131

(22) Filed: May 10, 2005

Related U.S. Application Data
(60) Provisional application No. 60/651,664, filed on Feb. 11, 2005.

(51) Int. Cl. G01R 31/28; G06F 11/00

(52) U.S. Cl. 714/741

(57) ABSTRACT

A virtual tester that simulates automatic test equipment (ATE). A translator converts program code of the ATE to pattern information and timing information. The virtual tester tests a software representation of a circuit, based on the program code of the ATE. The virtual tester uses the pattern information and/or the timing information to test the software representation of the circuit.

### BACKGROUND OF THE INVENTION

1. Field of the Invention

The present invention generally relates to software, and more specifically to software for simulating automatic test equipment.

2. Background

Advances in electronics technology are allowing electronics manufacturers to produce smaller, cheaper, and/or more complex circuits. For instance, a system-on-a-chip (SoC) device is a single integrated circuit that includes all of the hardware components (e.g., memory, microprocessor, digital signal processor (DSP)) necessary to perform the functions of a system, such as a cellular telephone or a digital camera.

Testing complex circuits, such as SoC devices, often requires complex testing techniques. Automated testing of the complex circuits generally provides cost benefits as compared to manual testing. However, automated testing and automated test equipment (ATE), also referred to as automatic test equipment, still can be very costly. For example, ATE equipment generally costs millions of dollars.

Automated testing can reduce the time necessary to test a complex circuit as compared to manual testing. However, the time available on ATE equipment to test a particular circuit is often limited by the number of different circuits that need to be tested. Moreover, the ATE equipment is typically used not only for testing a particular circuit, but also for debugging the ATE program code that is used to test the circuit. Debugging the program code is often time-intensive and reduces the time that the ATE equipment is available for the purpose of automated testing.

What are needed are a method, a system, and a computer program product that address one or more of the aforementioned shortcomings of conventional ATE and automated testing techniques.

### BRIEF SUMMARY OF THE INVENTION

The present invention provides a method and apparatus to simulate automatic test equipment (ATE). A software representation of the ATE, also referred to as a virtual tester, tests a software representation of a circuit, based on program code of the ATE. A translator converts the program code to pattern information and timing information. The virtual tester uses the pattern information and/or the timing information to test the software representation of the circuit. In an embodiment, the pattern information and/or the timing information is uncompiled. According to another embodiment, the virtual tester validates the pattern information and/or the timing information.

The virtual tester may include a software representation of one or more hardware characteristics of the ATE. For example, the virtual tester may determine whether a hardware restriction violation occurs with respect to pattern information or timing information associated with the ATE. In an embodiment, the virtual tester is platform independent. For instance, the virtual tester may be capable of simulating first ATE having a first platform and second ATE having a second platform.

Further features and advantages of the present invention, as well as the structure and operation of various embodiments of the present invention, are described in detail below with reference to the accompanying drawings.

### BRIEF DESCRIPTION OF THE DRAWINGS/FIGURES

The present invention is described with reference to the accompanying drawings. In the drawings, like reference numbers indicate identical or functionally similar elements. Additionally, the left most digit(s) of a reference number identifies the drawing in which the reference number first appears.

FIG. 1 illustrates a simulation system according to an embodiment of the present invention.

FIG. 2 illustrates a virtual tester according to an embodiment of the present invention.

FIG. 3 is a flowchart of a first method of simulating automated test equipment according to an embodiment of the present invention.

FIG. 4 is a flowchart of a second method of simulating automated test equipment according to an embodiment of the present invention.

FIG. 5 is a flowchart of a third method of simulating automated test equipment according to an embodiment of the present invention.

FIG. 6 is a flowchart of a fourth method of simulating automated test equipment according to an embodiment of the present invention.

FIG. 7 illustrates an example computer system, in which the present invention may be implemented as programmable code, according to an embodiment of the present invention.

### DETAILED DESCRIPTION OF THE INVENTION

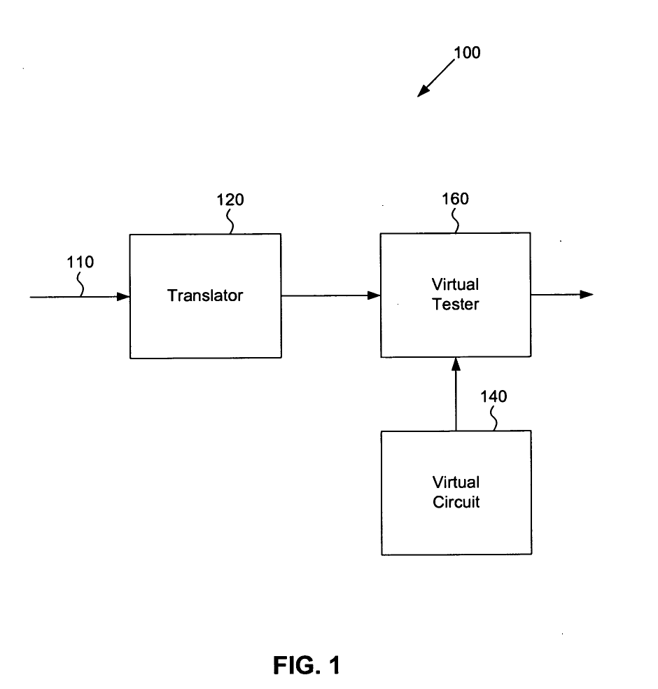

FIG. 1 illustrates a simulation system 100 according to an embodiment of the present invention. Simulation system 100 includes a translator 120, a virtual circuit 140, and a virtual tester 160. Translator 120 receives automated tester equipment (ATE) program code. For instance, the program code may be source code of ATE manufactured by any of a variety of ATE manufacturers, such as Agilent, Cadence Design Systems, Credence, Hewlett Packard, LTX, or Teradyne. Translator 120 translates the program code from one language to another. For example, translator 120 may translate the ATE program code to a suitable simulator software language, such as Verilog, Very High Speed Integrated Circuit (VHSIC) Hardware Description Language (VHDL), C, C+, or assembly.

Translator 120 converts the ATE program code based on instructions of a software program, such as a practical extraction report language (PERL) program. Translator 120 converts the ATE program code to pattern information and/or timing information. The pattern information indicates an operation to be performed at a pad/pin of virtual circuit 140 or a signal to be applied to the pad/pin. For example, the pattern information may indicate that a pad is to be switched from an input terminal to an output terminal, or vice versa. In another example, the pattern information may indicate that a pad is to be driven with a low or high voltage. The timing information indicates when the operation is to occur or when the signal is to be applied.

In one implementation, the pattern information includes rows and columns of bits. Each bit is defined by a row address and a column address. A row is associated with a particular cycle of a signal associated with virtual tester 160. According to a first embodiment, a signal cycle includes a “high” state and a “low” state, wherein the high state corresponds to a positive pulse and the low state corresponds to a negative pulse. According to a second embodiment, the signal cycle includes only one of the high state or the low state, and the rising and falling edges of the positive pulse or the falling and rising edges of the negative pulse define the signal cycle. By design, the Virtual pattern uses the same logical restrictions that the ATE pattern uses. One such logical restriction is that all signals applied to the pads/pins for a given pattern row must begin and end at the same time. This time interval for each pattern row is known as the “vector cycle time”.

Each column is uniquely associated with a particular pad of virtual circuit 140. A different row of the pattern information is used to test virtual circuit 140 at each signal cycle of virtual tester 160. The value of a bit having a row address and a column address specifies an operation to be performed or a signal to be applied at the pad associated with the column address and at the time associated with the row address. For example, the value of the bit may specify that the pad is to be connected to or disconnected from a power supply, a ground, or another pad. In another example, the value of the bit may specify that a voltage at the pad is to be increased or decreased.

Virtual circuit 140 is a simulated representation of the circuit to be tested by virtual tester 160. Virtual circuit 140 is a software representation of the circuit, based on a hardware description language (HDL). For example, virtual circuit 140 may be a postlayout netlist and/or a standard delay file (SDF). In another example, virtual circuit 140 is a register transfer level (RTL) netlist. Virtual circuit 140 simulates hardware characteristics of a circuit, such as mutual inductance between adjacent signal lines, coupling capacitance, etc. Virtual circuit 140 includes a plurality of models. Each model is a software representation of an element of the circuit, such as transmission lines, a resistor, a capacitor, an inductor, and/or a transistor, to provide some examples.

Virtual tester 160 tests virtual circuit 140 using the pattern information and/or the timing information associated with the program code of the ATE. The cause of a test failure is determined by reviewing output of virtual circuit 140 at each signal cycle of virtual tester 160. Models of virtual circuit 140 are connected by nodes. Virtual tester 160 analyzes a voltage at a particular node at a given signal cycle of virtual tester 160 to determine the cause of the test failure. Virtual tester 160 analyzes all output nodes for each signal cycle.

Virtual tester 160 stimulates virtual circuit 140 using signals comparable to those that an ATE uses to stimulate the circuit. The signals used by virtual tester 160 include formatters, pattern generators, and/or timing information. The signals are based on the pattern information and/or the timing information received from translator 120.

Virtual tester 160 stimulates virtual circuit 140 using one or more physical or virtual pin electronics cards (PECs). According to an embodiment, a different PEC is used to stimulate each pin of virtual circuit 140.

Simulation system 100 need not necessarily include translator 120. For example, in an embodiment, virtual tester 160 processes the ATE source code. Also, simulation system 100 need not necessarily include virtual circuit 140. Virtual tester 160 may test the physical circuit, rather than virtual circuit 140.

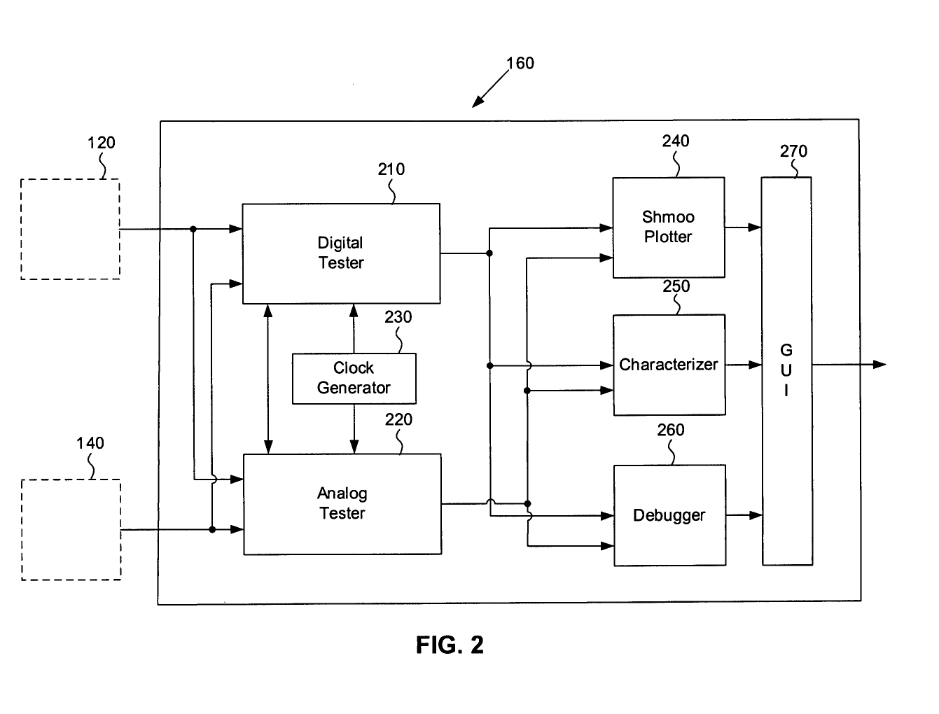

FIG. 2 illustrates a virtual tester 160 according to an embodiment of the present invention. Virtual tester 160 includes a digital tester 210, an analog tester 220, a signal generator 230, a shmoo plotter 240, a characterizer 250, a debugger 260, and a graphical user interface (GUI) 270. Virtual tester 160 performs device characterization and/or production testing. According to an embodiment, virtual tester 160 reduces the time necessary to debug ATE test patterns, as compared to conventional ATE.

Referring to FIG. 2, digital tester 210 provides a digital stimulus to virtual circuit 140. Digital tester 210 generates the digital stimulus based on pattern information and/or timing information received from translator 120. In an embodiment, digital tester 210 is capable of providing data to virtual circuit 140 at a rate of multiple gigabits per second (Gbps). Examples of a stimulus include a differential stimulus, a common mode stimulus, or a single-ended stimulus, to provide some examples.

Digital tester 210 determines or analyzes physical characteristics of virtual circuit 140, such as the function, timing, skew, or jitter of virtual circuit 140. Digital tester 210 performs one or more tests, including but not limited to a Serializer/Deserializer (SerDes) test, a Peripheral Component Interconnect (PCI) Express test, a HyperTransport test, a Rapid10 test, or a Source Synchronous Pin Electronics (SSPE) test. The SerDes test may include one or more of a functional test, a Pseudo Random Binary Sequence (PRBS) test, a jitter test, a receiver sensitivity test, an asynchronous port test, or a scan test. The jitter test tests jitter compliance, jitter tolerance, and/or jitter transfer. Digital tester 210 is capable of performing a test at a rate at which the operation being tested occurs in the associated system.

Analog tester 220 provides an analog stimulus to virtual circuit 140. The analog stimulus may be an audio, baseband, digital subscriber line (DSL), video, very high frequency (VHF), microwave, or time measurement signal, to provide some examples. The noise floor of the analog tester is set to resemble the noise floor of the ATE that virtual tester 160 is simulating.

Analog tester 220 may include one or more of a broadband alternating current (AC) tester, a radio frequency/microwave (RF/MW) tester, a digitizer, a Per-pin Parametric Measurement Unit (PPMU), or a waveform generator, to provide some examples. The broadband AC tester provides source and capture of analog signals across a broad bandwidth, such as 15 MHz. The broadband AC tester is used to test a virtual circuit for use in any suitable broadband system. The broadband AC tester tests a virtual circuit for any of a variety of applications including but not limited to personal computer (PC) audio, cellular baseband, code division multiple access (CDMA), wideband CDMA (W-CDMA), video, high definition television (HDTV), digital television (DTV), digital video disc (DVD), analog-to-digital conversion, digital-to-analog conversion, set-top box, and/or any digital subscriber line application (xDSL).

The RF/MW tester tests a virtual circuit 140 having a RF, MW, and/or mixed signal capability. The RF/MW tester is used to test a virtual circuit for use in any suitable wireless, RF, or MW system, including but not limited to a wireless local area network (LAN) system and/or a Bluetooth™ system. The RF/MW tester measures parameters, such as S-parameters, reflection coefficient, load resistance, noise figure, gain, gain ripple, error vector magnitude, or adjacent channel power ratio (ACPR). An operation performed by the RF/MW tester, such as modulation, signal capture, or frequency hopping, can be synchronized to digital tester 210. Frequency and amplitude switching operations of the RF/MW tester have settling times that are comparable to those of the ATE. The RF/MW tester may have a settling time of less than 2 milliseconds (ms) for frequency and/or amplitude switching. Frequency hopping may occur within 100 microseconds (μs).

The digitizer measures one or more of rise time, fall time, pulse width, random jitter, deterministic jitter, or bit error rate (BER), to provide some examples. The digitizer is capable of characterizing a high data rate circuit, such as a SerDes. The digitizer performs eye diagram testing and/or eye mask testing according to an embodiment.

The simulated PPMU has a force sense capability. According to an embodiment, the simulated PPMU forces a current and measures a resulting voltage. In another embodiment, the simulated PPMU forces a voltage and measures a resulting current.

Analog tester 220 may include a waveform generator to provide any of a variety of waveforms. The waveforms are based on any of a variety of time domain combinations. The waveform generator is capable of generating a local area network (LAN) waveform, such as a 1000BaseT 5-level (quinary) pulse amplitude modulation (PAM5) waveform, or a partial response maximum likelihood (PRML) waveform. The waveform generator generates a waveform having any suitable bit resolution (e.g., 10-bit resolution).

According to an embodiment, digital tester 210 and analog tester 220 are synchronized. For example, digital tester 210 can have a first clock, and analog tester 220 can have a second clock. The first clock and the second clock have substantially the same frequency and phase. In another example, digital tester 210 and analog tester 220 share the same clock.

Virtual tester 160 includes a signal generator 230. Signal generator 230 generates at least one signal for digital tester 210 and/or analog tester 220. Signal generator 230 is used to drive a virtual circuit 140, such as a simulated converter, a modem, or a data communication circuit.

Signal generator 230 is capable of operating at a high frequency with low jitter. According to an embodiment, signal generator 230 generates a signal having a frequency in a range from 5 megahertz (MHz) to 1 gigahertz (GHz). The signal may have a jitter of less than 1.5 picoseconds (ps) root mean square (rms), for example. Signal generator 230 receives a reference clock from a source, such as a digital or analog output of virtual circuit 140, an internal or external signal of simulation system 100, or a pattern generator of simulation system 100. Signal generator 230 may provide a clock based on the reference signal, though the scope of the invention is not limited in this respect.

According to an embodiment, virtual tester 160 is configured to simulate a device interface board (DIB), which can be referred to as a load board. A DIB is a circuit board that is coupled to conventional ATE to transport information from the ATE to the circuit. The simulation of the DIB is different for different types of circuits. Different types of devices can have different inputs and outputs. Virtual tester 160 may simulate hardware characteristics of the DIB, such as the amount of capacitance on a particular signal line.

In another embodiment, virtual tester 160 is configured to simulate a DIB module. A DIB module is a module that can be mounted in the z-space of a DIB to provide source and/or measurement capabilities to enhance the performance of the ATE. The DIB module reduces noise or distortion of the ATE or the length of a signal path. The DIB module may be a source, a digitizer, a clock fanout circuit, or an undersampling circuit, to provide some examples. The source provides multiple differential source channels, based on a single digital source. The digitizer converts an analog signal (e.g., a differential analog signal) to a digital representation of the analog signal. The clock fanout circuit provides multiple differential clocks based on a single source. The differential clocks may have frequencies that are different than the frequency of the single source. The undersampling circuit effectively compresses the bandwidth of the ATE. The undersampling circuit may increase the measurement dynamic range of the ATE.

Shmoo plotter 240 generates a shmoo plot, which shows pass/fail test results of virtual tester 160. The pass/fail test results are based on the relationship between two variables associated with virtual circuit 140, including but not limited to frequency, voltage, current, temperature, delay, power supply level, logic level, or load.

According to an embodiment, a variable is a parameter supplied to virtual circuit 140 by virtual tester 160. In another embodiment, a variable is a response or characteristic of virtual circuit 140 measured by virtual tester 160. A first variable is incremented within a predetermined range to determine the effect of each increment on a second variable. For example, shmoo plotter 240 may vary the frequency of the clock of virtual circuit 140 from 1 MHz to 2 MHz in 50 kHz steps to determine the maximum operable frequency of virtual circuit 140 or the output power of virtual circuit 140 at each step.

Characterizer 250 determines whether a test using particular pattern information fails in response to a pin/pad of virtual circuit 140 being set at a high voltage or a low voltage relative to ground. If the pin/pad is set at a high voltage, the test is referred to as an fₕᵢ test. If the pin/pad is set at a low voltage, the test is referred to as an fₗₒ test. An fₕᵢ or fₗₒ test failure may indicate that the pattern information is suitable for determining the high voltage threshold (Vᵢₕ) or the low voltage threshold (Vᵢₗ), respectively, of one or more pins/pads of virtual circuit 140 using the ATE or virtual tester 160.

Characterizer 250 validates pattern information and/or timing information associated with the ATE. The pattern information and/or timing information may be hand-generated or modified to accommodate a particular timeset for a timing search.

According to an embodiment, source code of the ATE is generated based on a block-level simulation, which is a simulation using a higher-level language than source code. Virtual tester 160 tests virtual circuit 140 using pattern information and/or timing information associated with the source code to determine whether the physical circuit is likely to operate properly based on the pattern information and/or the timing information.

Virtual tester 160 may include a threshold tester to determine Vᵢₕ and/or Vᵢₗ of the one or more pins/pads of virtual circuit 140. The threshold tester provides pattern information that results in a fₕᵢ or fₗₒ test failure to virtual circuit 140 to determine Vᵢₕ and/or Vᵢₗ. The threshold tester increments and/or decrements a voltage through a predetermined range to determine Vᵢₕ and/or Vᵢₗ.

Debugger 260 receives test information from digital tester 210 and/or analog tester 220 to facilitate determining the cause of a test failure. Debugger 260 organizes data obtained during one or more tests of digital tester 210 and/or analog tester 220. Debugger 260 formats the test data to be consistent with a format associated with an interface of the ATE platform simulated by virtual tester 160, such as but not limited to a DAI Signalscan™ interface, a Debussy nWave™ interface, or a DAI Simvision™ interface of Teradyne Catalyst ATE. Voltages at multiple nodes of virtual circuit 140 are displayed on a graphical user interface (GUI) 270 based on the output of debugger 260. Debugger 260 is used to determine whether a voltage at a node at a particular time is valid. Debugger 260 determines whether the voltage is within a certain range.

GUI 270 provides an interface to virtual tester 160 that is graphics-based. GUI 270 utilizes windows, menus, and/or icons to provide a graphical representation of the test results generated by virtual tester 160. GUI 270 facilitates loading, manipulating, and/or executing a test program, reviewing a test result, gathering data, debugging pattern information or timing information based on the ATE source code, or debugging the test program, to provide some examples.

A mouse is used to manipulate the windows, icons, or information associated with a window or icon. GUI 270 may be any suitable GUI, including but not limited to Windows, Macintosh (Mac), Motif, GNU network object model environment (GNOME), or K desktop environment (KDE). According to an embodiment, virtual tester 160 includes a text-based interface rather than GUI 270.

Virtual tester 160 may be compatible with a waveform viewer, though the scope of the present invention is not limited in this respect. According to an embodiment, virtual tester 160 includes a waveform viewer. The waveform viewer may be included in GUI 270. The waveform viewer provides a graphical representation of a signal with respect to time. Virtual tester 160 may incorporate any of a variety of waveform viewers, including but not limited to ModelSim™ by Model Technology, Simvision™ by Cadence Design Systems, Inc., Signalscan™ by Cadence Design Systems, Inc., or Debussy® nWave™ by Novas Software, Inc.

Virtual tester 160 supports any of a variety of simulator platforms, such as ncverilog, ncsim, ncvlog, ncvhdl, or ncelab by Cadence Design Systems, Inc; ModelSim™, vsim, or vlog by Model Technology Inc; VCS by Synopsys; or Tiger or Catalyst by Teradyne.

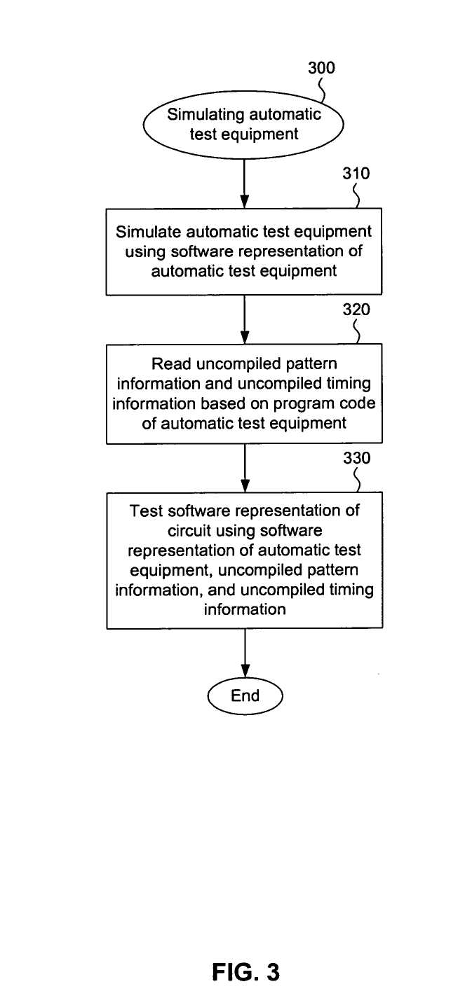

FIG. 3 illustrates a flowchart 300 of a method for simulating automatic test equipment in accordance with an embodiment of the present invention. The invention, however, is not limited to the description provided by flowchart 300. Rather, it will be apparent to persons skilled in the relevant art(s) from the teachings provided herein that other functional flows are within the scope and spirit of the present invention.

Flowchart 300 will be described with continued reference to example simulation system 100 described above in reference to FIG. 1, though the method is not limited to that embodiment.

Referring now to FIG. 3, virtual tester 160 simulates ATE using a software representation of the ATE, as shown at block 310. Virtual tester 160 reads uncompiled pattern information and uncompiled timing information based on program code of the ATE, as shown at block 320. Translator 120 converts the program code of the ATE to the uncompiled pattern information and the uncompiled timing information, though the scope of the invention is not limited in this respect. Virtual tester 160 tests a software representation of a circuit using the software representation of the ATE, the uncompiled pattern information, and the uncompiled timing information, as shown at block 330. In an embodiment, virtual tester 160 re-tests the software representation of the circuit without having to compile or re-compile the pattern information and/or the timing information.

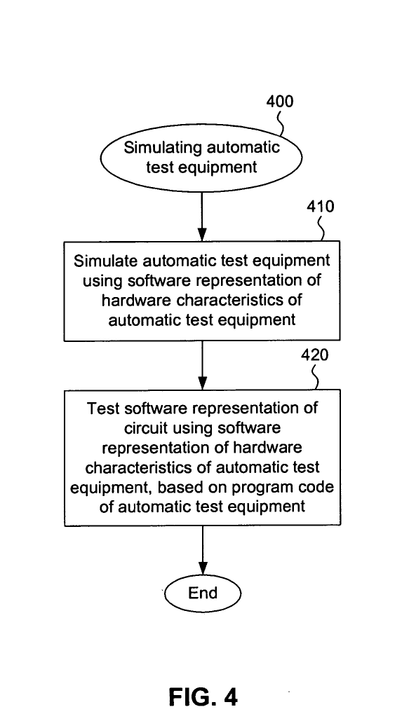

FIG. 4 illustrates a flowchart 400 of a method for simulating automatic test equipment in accordance with an embodiment of the present invention. The invention, however, is not limited to the description provided by flowchart 400. Rather, it will be apparent to persons skilled in the relevant art(s) from the teachings provided herein that other functional flows are within the scope and spirit of the present invention.

Flowchart 400 will be described with continued reference to example simulation system 100 described above in reference to FIG. 1, though the method is not limited to that embodiment.

Referring now to FIG. 4, virtual tester 160 simulates ATE using a software representation of hardware characteristics of the ATE, as shown at block 410. The hardware characteristic may be the test cycle of virtual tester 160, the number of timing sets that have been used during a test, the number of pins that are tested or are used for testing, the pulse width of an input of virtual tester 160, the strobe width of the ATE (i.e., minimum time period within which an output of the ATE can be detected), the relative timing of input signals to virtual tester 160 (i.e., timing between edges of signals at virtual pins of virtual tester 160), or an edge-to-edge regeneration time (i.e., time required to switch a digital signal to a “high” state after switching to a “low” state or vice versa), to provide some examples.

According to an embodiment, a hardware characteristic is a characteristic associated with a pull-up component or a pull-down component. A pull-up component is a component that causes a voltage of the ATE to become or remain high. A pull-down component is a component that causes a voltage of the ATE to become or remain low. In another embodiment, the hardware characteristic is an effect that an element, such as a pull-up component or a pull-down component, has on another signal. The pull-up or pull-down component has an associated resistor-capacitor (RC) time constant. The voltage at a pin/pad of the ATE does not change instantaneously. Virtual tester 160 simulates a delay associated with the element.

According to an embodiment, a hardware characteristic of the ATE is a hardware characteristic of a device interface board (DEB) associated with the ATE. The hardware characteristic may be a trace length delay, a characteristic capacitance, or a contact resistance of a relay of the DIB, to provide some examples.

Virtual tester 160 tests a software representation of a circuit using the software representation of the hardware characteristics of the ATE, based on program code of the ATE, as shown at block 420.

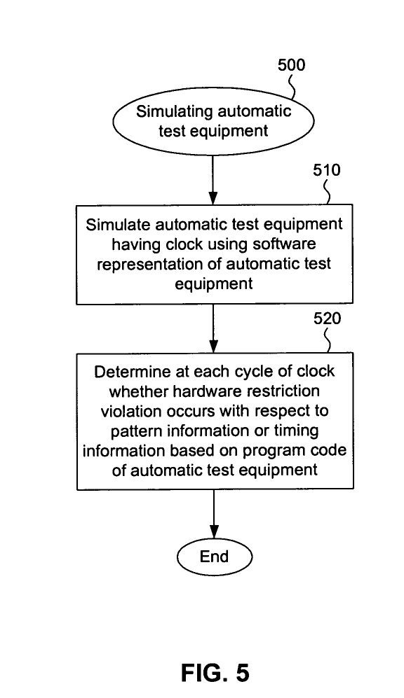

FIG. 5 illustrates a flowchart 500 of a method for simulating automatic test equipment in accordance with an embodiment of the present invention. The invention, however, is not limited to the description provided by flowchart 500. Rather, it will be apparent to persons skilled in the relevant art(s) from the teachings provided herein that other finctional flows are within the scope and spirit of the present invention.

Flowchart 500 will be described with continued reference to example simulation system 100 described above in reference to FIG. 1, though the method is not limited to that embodiment.

Referring now to FIG. 5, virtual tester 160 simulates ATE having a clock using a software representation of the ATE, as shown at block 510. At block 520, virtual tester 160 determines at each cycle of the clock whether a hardware restriction violation occurs with respect to pattern information or timing information based on program code of the ATE. A hardware restriction violation occurs in response to a hardware characteristic of the ATE exceeding a limitation of the ATE.

In an embodiment, the ATE is not capable of detecting a pulse width having a duration less than a particular amount of time. For example, the ATE may not be capable of providing a valid output in response to receiving such a short input pulse. In such an embodiment, virtual tester 160 compares the duration of the input pulse to the minimum pulse width threshold of the ATE. If the pulse width of the input pulse is less than the minimum pulse width, then virtual tester 160 determines that a hardware restriction violation occurs.

In an embodiment, translator 120 converts the program code to the pattern information and/or the timing information on the fly. In other words, translator 120 converts program code to pattern information and/or timing information at each signal cycle of virtual tester 160. Virtual tester 160 utilizes the pattern information and/or timing information converted at a particular signal cycle to determine whether a hardware restriction violation occurs at that signal cycle.

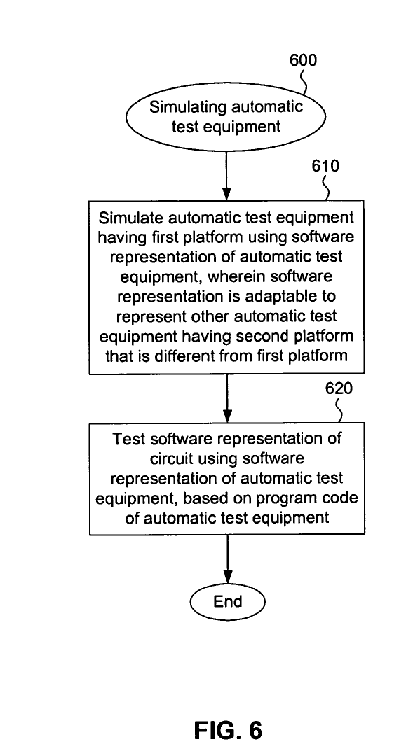

FIG. 6 illustrates a flowchart 600 of a method for simulating automatic test equipment in accordance with an embodiment of the present invention. The invention, however, is not limited to the description provided by flowchart 600. Rather, it will be apparent to persons skilled in the relevant art(s) from the teachings provided herein that other fuictional flows are within the scope and spirit of the present invention.

Flowchart 600 will be described with continued reference to example simulation system 100 described above in reference to FIG. 1, though the method is not limited to that embodiment.

Referring now to FIG. 6, virtual tester 160 simulates ATE having a first platform using a software representation of the ATE, as shown at block 610. The first platform may be a platform provided by Agilent, Cadence Design Systems, Model Technology, Synopsys, or Teradyne, to provide some examples. If the first platform is Teradyne's Tiger platform, for example, the software representation may be adaptable to represent other ATE having a second platform that is different from Teradyne's Tiger platform, such as Teradyne's Catalyst platform or Cadence Design System's ncvhdl platform. At block 620, virtual tester 160 tests a software representation of a circuit using the software representation of the ATE based on program code of the ATE.

Virtual tester 160 validates the pattern information and/or the timing information associated with the program code of the ATE. In an embodiment, virtual tester 160 validates hand-generated pattern information and/or hand-generated timing information. Pattern information or timing information may be hand-modified to include a particular time set for a timing search, for example.

According to an embodiment, virtual tester 160 validates pattern information and/or the timing information based on ATE program code that is generated using a block level simulation. Virtual tester 160 tests virtual circuit 140 to determine whether the physical circuit is capable of performing properly based on the pattern information and/or the timing information.

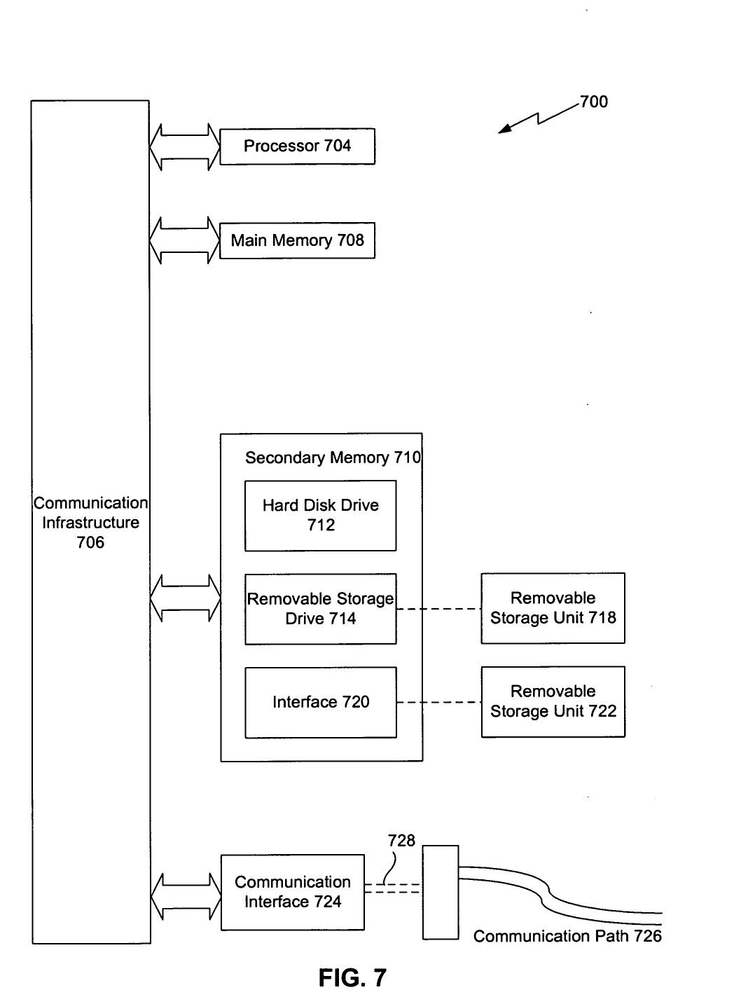

FIG. 7 illustrates an example computer system 700, in which the present invention may be implemented as programmable code. Various embodiments of the invention are described in terms of this example computer system 700. After reading this description, it will become apparent to a person skilled in the art how to implement the invention using other computer systems and/or computer architectures.

Computer system 700 includes one or more processors, such as processor 704. Processor 704 may be any type of processor, including but not limited to a special purpose or a general purpose digital signal processor. Processor 704 is connected to a communication infrastructure 706 (for example, a bus or network). Various software implementations are described in terms of this exemplary computer system. After reading this description, it will become apparent to a person skilled in the art how to implement the invention using other computer systems and/or computer architectures.

Computer system 700 also includes a main memory 708, preferably random access memory (RAM), and may also include a secondary memory 710. Secondary memory 710 may include, for example, a hard disk drive 712 and/or a removable storage drive 714, representing a floppy disk drive, a magnetic tape drive, an optical disk drive, etc. The removable storage drive 714 reads from and/or writes to a removable storage unit 718 in a well known manner. Removable storage unit 718, represents a floppy disk, magnetic tape, optical disk, etc. which is read by and written to by removable storage drive 714. As will be appreciated, removable storage unit 718 includes a computer usable storage medium having stored therein computer software and/or data.

In alternative implementations, secondary memory 710 may include other similar means for allowing computer programs or other instructions to be loaded into computer system 700. Such means may include, for example, a removable storage unit 722 and an interface 720. Examples of such means may include a program cartridge and cartridge interface (such as that found in video game devices), a removable memory chip (such as an EPROM, or PROM) and associated socket, and other removable storage units 722 and interfaces 720 which allow software and data to be transferred from removable storage unit 722 to computer system 700.

Computer system 700 may also include a communication interface 724. Communication interface 724 allows software and data to be transferred between computer system 700 and external devices. Examples of communication interface 724 may include a modem, a network interface (such as an Ethernet card), a communication port, a Personal Computer Memory Card International Association (PCMCIA) slot and card, etc. Software and data transferred via communication interface 724 are in the form of signals 728 which may be electronic, electromagnetic, optical, or other signals capable of being received by communication interface 724. These signals 728 are provided to communication interface 724 via a communication path 726. Communication path 726 carries signals 728 and may be implemented using wire or cable, fiber optics, a phone line, a cellular phone link, a radio frequency link, or any other suitable communication channel. For instance, communication path 726 may be implemented using a combination of channels.

In this document, the terms “computer program medium” and “computer usable medium” are used generally to refer to media, such as removable storage unit 718, removable storage unit 722, a hard disk installed in hard disk drive 712, and signals 728. These computer program products are means for providing software to computer system 700.

Computer programs (also called computer control logic) are stored in main memory 708 and/or secondary memory 710. Computer programs may also be received via communication interface 724. Such computer programs, when executed, enable computer system 700 to implement the present invention as discussed herein. Accordingly, such computer programs represent controllers of computer system 700. Where the invention is implemented using software, the software may be stored in a computer program product and loaded into computer system 700 using removable storage drive 714, interface 720, hard disk drive 712, or communication interface 724, to provide some examples.

In alternative embodiments, the invention can be implemented as control logic in hardware, firmware, or software or any combination thereof.

### CONCLUSION

Example embodiments of the methods, systems, and components of the present invention have been described herein. As noted elsewhere, these example embodiments have been described for illustrative purposes only, and are not limiting. Other embodiments are possible and are covered by the invention. Such other embodiments will be apparent to persons skilled in the relevant art(s) based on the teachings contained herein. Thus, the breadth and scope of the present invention should not be limited by any of the above described exemplary embodiments, but should be defined only in accordance with the following claims and their equivalents.

1. A method, comprising:
simulating automatic test equipment using a software representation of hardware characteristics of the automatic test equipment; and
testing a software representation of a circuit using the software representation of the hardware characteristics of the automatic test equipment, based on program code of the automatic test equipment.

2. The method of claim 1, further comprising converting the program code to pattern information and timing information, wherein testing the software representation of the circuit is based on the pattern information and the timing information.

3. The method of claim 1, further comprising validating the program code based on testing the software representation of the circuit.

4. The method of claim 1, further comprising simulating a device interface board using a software representation of the device interface board, wherein testing the software representation of the circuit includes testing the software representation of the circuit using the software representation of the device interface board.

5. A method, comprising:
simulating automatic test equipment having a signal using a software representation of the automatic test equipment; and
determining at each cycle of the signal whether a hardware restriction violation occurs with respect to pattern information or timing information based on program code of the automatic test equipment.

6. The method of claim 5, wherein simulating the automatic test equipment includes selectively simulating the automatic test equipment using a software representation of the automatic test equipment in accordance with a first platform or a second platform.

7. The method of claim 5, further comprising validating the program code based on testing a software representation of a circuit.

8. The method of claim 5, further comprising simulating a device interface board using a software representation of the device interface board, wherein determining is based on the software representation of the device interface board.

9. A method, comprising:
selectively simulating automatic test equipment in accordance with a first platform or a second platform using a software representation of the automatic test equipment; and
testing a software representation of a circuit using the software representation of the automatic test equipment, based on program code of the automatic test equipment.

10. The method of claim 9, wherein simulating the automatic test equipment includes simulating the automatic test equipment using a software representation of hardware characteristics of the automatic test equipment.

11. The method of claim 10, further comprising converting the program code to pattern information and timing information, wherein testing the software representation of the circuit is based on the pattern information and the timing information.

12. The method of claim 9, further comprising validating the program code based on testing the software representation of the circuit.

13. The method of claim 9, further comprising simulating a device interface board using a software representation of the device interface board, wherein testing the software representation of the circuit includes testing the software representation of the circuit using the software representation of the device interface board.

14. An article of manufacture comprising a computer-readable medium for storing computer instructions that enable a processor-based system to:
simulate automatic test equipment using a software representation of hardware characteristics of the automatic test equipment; and
test a software representation of a circuit using the software representation of the hardware characteristics of the automatic test equipment, based on program code of the automatic test equipment.

15. The article of claim 14, further storing instructions to enable a processor-based system to convert the program code to pattern information and timing information, wherein the instructions to enable the processor-based system to test the software representation of the circuit include instructions to enable the processor-based system to test the software representation of the circuit based on the pattern information and the timing information.

16. The article of claim 14, further storing instructions to enable a processor-based system to validate the program code in response to the software representation of the circuit being tested.

17. The article of claim 14, further storing instructions to enable a processor-based system to simulate a device interface board using a software representation of the device interface board, wherein the instructions to enable the processor-based system to test the software representation of the circuit include instructions to enable the processor-based system to test the software representation of the circuit using the software representation of the device interface board.

18. An article of manufacture comprising a computer-readable medium for storing computer instructions that enable a processor-based system to:
simulate automatic test equipment using a software representation of the automatic test equipment; and
determine at each cycle of a signal whether a hardware restriction violation occurs with respect to pattern information or timing information based on program code of the automatic test equipment.

19. The article of claim 18, wherein the instructions to enable the processor-based system to simulate the automatic test equipment include instructions to enable the processor-based system to simulate the automatic test equipment using a software representation of the automatic test equipment in accordance with a first platform or a second platform.

20. The article of claim 18, further storing instructions to enable a processor-based system to validate the program code in response to a software representation of a circuit being tested.

21. The article of claim 18, further storing instructions to enable a processor-based system to simulate a device interface board using a software representation of the device interface board.

22. An article of manufacture comprising a computer-readable medium for storing computer instructions that enable a processor-based system to:
selectively simulate automatic test equipment in accordance with a first platform or a second platform using a software representation of the automatic test equipment; and
test a software representation of a circuit using the software representation of the automatic test equipment, based on program code of the automatic test equipment.

23. The article of claim 22, wherein the instructions to enable the processor-based system to simulate the automatic test equipment include instructions to enable the processor-based system to simulate the automatic test equipment using a software representation of hardware characteristics of the automatic test equipment.

24. The article of claim 23, further storing instructions to enable a processor-based system to convert the program code to pattern information and timing information, wherein the instructions to enable the processor-based system to test the software representation of the circuit include instructions to enable the processor-based system to test the software representation of the circuit based on the pattern information and the timing information.

25. The article of claim 22, further storing instructions to enable a processor-based system to validate the program code in response to the software representation of the circuit being tested.

26. The article of claim 22, further storing instructions to enable a processor-based system to simulate a device interface board using a software representation of the device interface board, wherein the instructions to enable the processor-based system to test the software representation of the circuit include instructions to enable the processor-based system to test the software representation of the circuit using the software representation of the device interface board.
